(19) United States
(12) Patent Application Publication
(10) Pub. No.: US 2024/0365512 A1
(43) Pub. Date: Oct. 31, 2024

(54) THERMAL DIFFUSION DEVICE AND ELECTRONIC APPARATUS

(71) Applicant: Murata Manufacturing Co., Ltd., Nagaokakyo-shi (JP)

(72) Inventor: Tatsuhiro NUMOTO, Nagaokakyo-shi (JP)

(21) Appl. No.: 18/767,209

(22) Filed: Jul. 9, 2024

Related U.S. Application Data
(63) Continuation of application No. PCT/JP2023/000095, filed on Jan. 5, 2023.

(30) Foreign Application Priority Data
Jan. 25, 2022 (JP) 2022-009468

(51) Int. Cl. H05K 7/20; G06F 1/20

(52) U.S. Cl. CPC H05K 7/20336; G06F 1/203; H05K 7/20327

(57) ABSTRACT

A thermal diffusion device that includes: a housing having a first inner wall surface and a second inner wall surface that face each other in a thickness direction and define and internal space; a working medium enclosed in the internal space of the housing; and a wick in the internal space of the housing. The wick includes: a support that is in contact with the first inner wall surface; a perforated body that is in contact with the support, the perforated body having a through-hole that penetrates the perforated body in the thickness direction; and a protrusion portion on a peripheral edge of the through-hole and extending in a direction toward the first inner wall surface.

### CROSS REFERENCE TO RELATED APPLICATIONS

The present application is a continuation of International application No. PCT/JP2023/000095, filed Jan. 5, 2023, which claims priority to Japanese Patent Application No. 2022-009468, filed Jan. 25, 2022, the entire contents of each of which are incorporated herein by reference.

### TECHNICAL FIELD

The present disclosure relates to a thermal diffusion device and an electronic apparatus.

### BACKGROUND ART

In recent years, an amount of heat generation is increased due to the high integration and high performance of elements. In addition, a heat generation density is increased as a product is reduced in size, and it is thus important to take countermeasures to radiate heat. Such a situation is particularly conspicuous in the field of mobile terminals such as a smartphone and a tablet. A graphite sheet or the like is used as a heat countermeasure member in many cases, but the graphite sheet is not sufficient in a heat transport amount, and thus using various heat countermeasure members is studied. Among these, as a thermal diffusion device capable of highly effectively diffusing heat, using a vapor chamber which is a planar heat pipe is studied.

The vapor chamber has a structure in which a working medium (also referred to as a working fluid) and a wick that transports the working medium using capillary force are enclosed in the inside of a housing. The working medium absorbs heat from a heat generating element such as an electronic component in an evaporation portion that absorbs heat from the heat generating element, to evaporate in the vapor chamber, moves in the vapor chamber, and is cooled to return to a liquid phase. The working medium that has returned to the liquid phase moves again to the evaporation portion on the heat generating element side due to the capillary force of the wick, and cools the heat generating element. With repetition of the above-described process, the vapor chamber can independently operate without an external power to two-dimensionally diffuse heat at a high speed by using latent heat of evaporation and latent heat of condensation of the working medium.

Patent Document 1 discloses a thermal ground plane as an example of a vapor chamber. The thermal ground plane described in Patent Document 1 includes a first planar substrate member, a plurality of micropillars disposed on the first planar substrate member, a mesh that is bonded to at least some of the micropillars, a vapor core disposed in at least one of the first planar substrate member, the micropillars, and the mesh, and a second planar substrate member disposed on the first planar substrate member, in which the mesh isolates the micropillars from the vapor core, and the first planar substrate member and the second planar substrate member surround the micropillars, the mesh, and the vapor core.
Patent Document 1: U.S. Pat. No. 10,527,358

### SUMMARY OF THE DISCLOSURE

In the vapor chamber as described in Patent Document 1, a wick is formed of a pillar such as the micropillar and a perforated body such as the mesh. As the perforated body of the vapor chamber, for example, a perforated body in which a hole portion is formed in a metal plate by etching or the like is used. In such a perforated body, a surface of the perforated body and a surface surrounded by a peripheral edge of the hole portion are flush with each other in a portion on a liquid flow passage side of the working medium. Then, the capillary force is generated by the surface surrounded by the peripheral edge of the hole portion being in contact with the working medium in a portion on the liquid flow passage side of the working medium. However, for example, in a case where a liquid amount of the working medium is small due to an issue in a process, such as a small liquid feeding amount of the working medium in a feeding process during vapor chamber manufacturing, the surface surrounded by the peripheral edge of the hole portion does not come into contact with the working medium in the portion of the perforated body on the liquid flow passage side of the working medium, and thus there is a risk that the capillary force is less likely to be generated in the wick. In such a case, since the movement of the working medium is less likely to occur in the vapor chamber, there is an issue in that the heat uniformity performance and the heat transport performance of the vapor chamber are deteriorated.

The present disclosure has been made in order to solve the above-described issue, and an object of the present disclosure is to provide a thermal diffusion device with which a deterioration in heat uniformity performance and heat transport performance can be suppressed even in a case where a liquid amount of a working medium is small. Another object of the present disclosure is to provide an electronic apparatus including the thermal diffusion device.

The present disclosure provides a thermal diffusion device including: a housing having a first inner wall surface and a second inner wall surface that face each other in a thickness direction and define an internal space; a working medium enclosed in the internal space of the housing; and a wick in the internal space of the housing, in which the wick includes: a support that is in contact with the first inner wall surface; a perforated body that is in contact with the support, the perforated body having a through-hole that penetrates the perforated body in the thickness direction; and a protrusion portion on a peripheral edge of the through-hole and extending in a direction toward the first inner wall surface.

The present disclosure provides an electronic apparatus including: the thermal diffusion device according to the present disclosure.

According to the present disclosure, it is possible to provide the thermal diffusion device with which the deterioration in the heat uniformity performance and the heat transport performance can be suppressed even in a case where the liquid amount of the working medium is small. Further, according to the present disclosure, it is possible to provide the electronic apparatus including the thermal diffusion device.

### BRIEF DESCRIPTION OF THE DRAWINGS

FIG. 1 is a perspective view schematically illustrating an example of a thermal diffusion device according to the present disclosure.

FIG. 2 is an example of a cross-sectional view of the thermal diffusion device illustrated in FIG. 1, which is taken along a line II-II.

FIG. 3A is a partially enlarged cross-sectional view schematically illustrating examples of a wick and a working medium constituting the thermal diffusion device illustrated in FIG. 2. FIG. 3B is a perspective view schematically illustrating a shape of a protrusion portion of the wick illustrated in FIG. 3A. FIG. 3C is a perspective view schematically illustrating another example of the shape of the protrusion portion of the wick illustrated in FIG. 3A.

FIG. 4A is an example of a plan view of the wick illustrated in FIG. 3A when viewed from a support side. FIG. 4B is another example of a plan view of the wick illustrated in FIG. 3A when viewed from the support side.

FIG. 5A is a partially enlarged cross-sectional view schematically illustrating a first modification example of the protrusion portion. FIG. 5B is a perspective view schematically illustrating a shape of the protrusion portion illustrated in FIG. 5A.

FIG. 6A is a partially enlarged cross-sectional view schematically illustrating a second modification example of the protrusion portion. FIG. 6B is a perspective view schematically illustrating a shape of the protrusion portion illustrated in FIG. 6A.

FIG. 7-1A is a partially enlarged cross-sectional view schematically illustrating a third modification example of the protrusion portion. FIG. 7-1B is a perspective view schematically illustrating a shape of the protrusion portion illustrated in FIG. 7-1A.

FIG. 7-2A is a partially enlarged cross-sectional view schematically illustrating another example of the protrusion portion illustrated in FIG. 7-1A. FIG. 7-2B is a perspective view schematically illustrating a shape of the protrusion portion illustrated in FIG. 7-2A.

FIG. 7-3A is a partially enlarged cross-sectional view schematically illustrating another example of the protrusion portion illustrated in FIG. 7-1A. FIG. 7-3B is a perspective view schematically illustrating a shape of the protrusion portion illustrated in FIG. 7-3A.

FIG. 8 is a partially enlarged cross-sectional view schematically illustrating a fourth modification example of the protrusion portion.

FIG. 9 is a partially enlarged cross-sectional view of a part schematically illustrating a fifth modification example of the protrusion portion.

FIG. 10 is a partially enlarged cross-sectional view schematically illustrating a first modification example of the wick.

FIG. 11 is a partially enlarged cross-sectional view schematically illustrating a first modification example of the protrusion portion in the wick illustrated in FIG. 10.

FIG. 12 is a partially enlarged cross-sectional view schematically illustrating a second modification example of the protrusion portion in the wick illustrated in FIG. 10.

FIG. 13 is a partially enlarged cross-sectional view schematically illustrating a second modification example of the wick.

FIG. 14 is a plan view schematically illustrating a third modification example of the wick.

FIG. 15 is a cross-sectional view schematically illustrating a first modification example of the thermal diffusion device.

FIG. 16 is a cross-sectional view schematically illustrating a second modification example of the thermal diffusion device.

FIG. 17 is a plan view of a first modification example of the wick illustrated in FIG. 3A when viewed from the perforated body side.

FIG. 18 is a cross-sectional view of the wick illustrated in FIG. 17, which is taken along a line A-A.

FIG. 19 is a view illustrating a definition of the protrusion portion in the wick illustrated in FIG. 11.

FIG. 20 is a view illustrating a definition of the protrusion portion in the wick illustrated in FIG. 18.

### DESCRIPTION OF THE PREFERRED EMBODIMENTS

Hereinafter, a thermal diffusion device according to the present disclosure will be described.

However, the present disclosure is not limited to the following embodiments, and can be applied after being appropriately modified without changing the gist of the present disclosure. The present disclosure also includes combinations of two or more separate preferred configurations of the present disclosure, which will be described below.

Hereinafter, a vapor chamber will be described as an example of the thermal diffusion device according to the embodiment of the present disclosure. The thermal diffusion device according to the present disclosure can also be applied to a thermal diffusion device such as a heat pipe.

The drawings illustrated below are schematic drawings, and dimensions, aspect ratios, and the like therein may be different from those of an actual product.

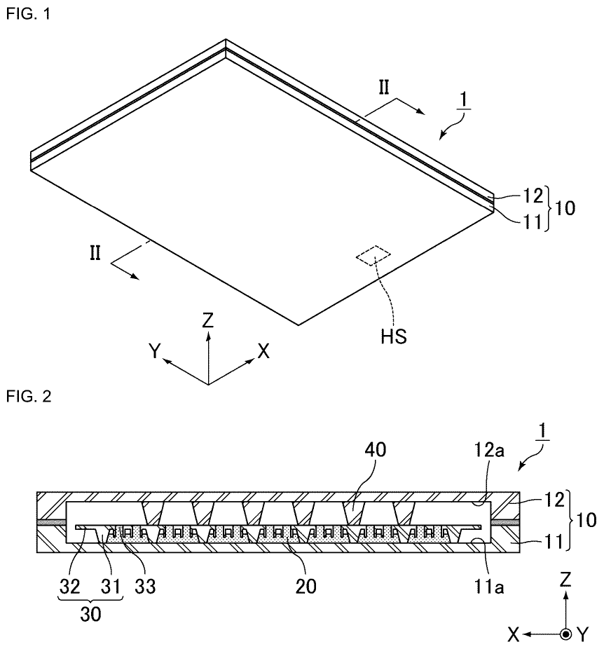

FIG. 1 is a perspective view schematically illustrating an example of the thermal diffusion device according to the present disclosure. FIG. 2 is an example of a cross-sectional view of the thermal diffusion device illustrated in FIG. 1, which is taken along a line II-II.

A vapor chamber (thermal diffusion device) 1 illustrated in FIGS. 1 and 2 includes a hollow housing 10 that is sealed in an airtight state. The housing 10 has a first inner wall surface 11a and a second inner wall surface 12a that face each other in a thickness direction Z. The vapor chamber 1 further includes a working medium 20 enclosed in an internal space of the housing 10 and a wick 30 disposed in the internal space of the housing 10.

The housing 10 is set with an evaporation portion for evaporating the enclosed working medium 20. As illustrated in FIG. 1, a heat source HS, which is a heat generating element, is disposed on an outer wall surface of the housing 10. Examples of the heat source HS include electronic components of an electronic apparatus, such as a central processing unit (CPU). A portion of the internal space of the housing 10, which is the vicinity of the heat source HS and is heated by the heat source HS, corresponds to the evaporation portion.

It is preferable that the vapor chamber 1 is planar as a whole. That is, it is preferable that the housing 10 is planar as a whole. Here, the term “planar” includes a plate shape and a sheet shape, and means a shape in which a dimension in a width direction X (hereinafter, referred to as a width) and a dimension in a length direction Y (hereinafter, referred to as a length) are substantially larger than a dimension in the thickness direction Z (hereinafter, referred to as a thickness or a height), for example, a shape in which the width and the length are equal to or greater than 10 times the thickness, preferably equal to or greater than 100 times the thickness.

A size of the vapor chamber 1, that is, a size of the housing 10 is not particularly limited. A width and a length of the vapor chamber 1 can be appropriately set depending on the intended use of the vapor chamber 1. Each of the width and the length of the vapor chamber 1 is, for example, 5 mm to 500 mm, 20 mm to 300 mm, or 50 mm to 200 mm. The width and the length of the vapor chamber 1 may be the same as each other or different from each other.

It is preferable that the housing 10 is composed of a first sheet 11 and a second sheet 12 that face each other with outer edge portions thereof being bonded to each other.

In a case where the housing 10 is composed of the first sheet 11 and the second sheet 12, materials of the first sheet 11 and the second sheet 12 are not particularly limited as long as the materials have characteristics, such as thermal conductivity, strength, flexibility, and flexibility, suitable for use as the vapor chamber. The materials of the first sheet 11 and the second sheet 12 are preferably a metal (for example, copper, nickel, aluminum, magnesium, titanium, iron, or an alloy containing these materials as main components), and particularly preferably copper. Although the materials of the first sheet 11 and the second sheet 12 may be the same as each other or different from each other, it is preferable that the materials are the same as each other.

In a case where the housing 10 is composed of the first sheet 11 and the second sheet 12, the first sheet 11 and the second sheet 12 are bonded to each other at the outer edge portions thereof. A method of such bonding is not particularly limited, and for example, laser welding, resistance welding, diffusion bonding, soldering, tungsten-inert gas (TIG) welding, ultrasonic bonding, or resin sealing can be used, and laser welding, resistance welding, or soldering can be preferably used.

Although thicknesses of the first sheet 11 and the second sheet 12 are not particularly limited, each thickness is preferably 10 μm to 200 μm, more preferably 30 μm to 100 μm, and still more preferably 40 μm to 60 μm. The thicknesses of the first sheet 11 and the second sheet 12 may be the same as each other or different from each other. In addition, the thickness of each the first sheet 11 and the second sheet 12 may be constant as a whole, or may be partially thin.

Shapes of the first sheet 11 and the second sheet 12 are not particularly limited. For example, each of the first sheet 11 and the second sheet 12 may have a shape in which the outer edge portion is thicker than a portion other than the outer edge portion.

Although a thickness of the entire vapor chamber 1 is not particularly limited, the thickness is preferably 50 μm to 500 μm.

A planar shape of the housing 10 when viewed in the thickness direction Z is not particularly limited, and examples thereof include a polygonal shape such as a triangular shape or a rectangular shape, a circular shape, an elliptical shape, and a shape obtained by combining these shapes. In addition, the planar shape of the housing 10 may be an L-shape, a C-shape (U-shape), a stair shape, or the like. In addition, the housing 10 may have a penetrating port. The planar shape of the housing 10 may be a shape matching the intended use of the vapor chamber, a shape of a portion in which the vapor chamber is inserted, and other nearby components.

The working medium 20 is not particularly limited as long as the working medium 20 can cause a gas-liquid phase change under an environment inside the housing 10, and, for example, water, alcohols, CFC substitutes, and the like can be used. For example, the working medium 20 is an aqueous compound and is preferably water.

The wick 30 has a capillary structure capable of moving the working medium 20 by using capillary force.

A size and a shape of the wick 30 are not particularly limited, but it is preferable that the wicks 30 are continuously disposed in the internal space of the housing 10. The wick 30 may be disposed in the entire internal space of the housing 10 when viewed in the thickness direction Z, or the wick 30 may be disposed in a part of the internal space of the housing 10 when viewed in the thickness direction Z.

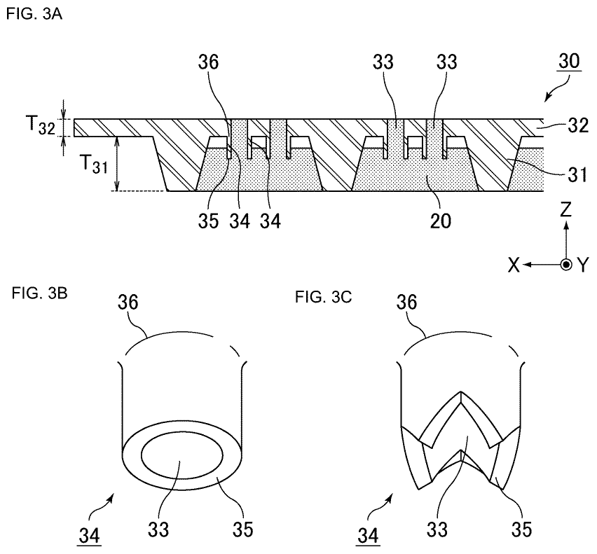

FIG. 3A is a partially enlarged cross-sectional view schematically illustrating examples of the wick and the working medium constituting the thermal diffusion device illustrated in FIG. 2.

As illustrated in FIGS. 2 and 3A, the wick 30 includes a support 31 that is in contact with the first inner wall surface 11a, and a perforated body 32 that is in contact with the support 31.

In the wick 30, the perforated body 32 is made of a material that is the same as a material of the support 31. In a case where the perforated body 32 is made of the material that is the same as the material of the support 31, the materials of the support 31 and the perforated body 32 are not particularly limited, and examples thereof include a resin, a metal, ceramics, a mixture thereof, and a laminate. A metal is preferable as the materials of the support 31 and the perforated body 32.

In the wick 30, the support 31 and the perforated body 32 may be integrally formed. In the present specification, the phrase “the support 31 and the perforated body 32 are integrally formed” means that there is no interface between the support 31 and the perforated body 32, and specifically means that a boundary between the support 31 and the perforated body 32 cannot be discriminated.

The wick 30 in which the support 31 and the perforated body 32 are integrally formed can be manufactured by, for example, an etching technique, a printing technique using a multilayer coating, or other multilayer techniques.

In the wick 30, in a case where the perforated body 32 is made of the material that is the same as the material of the support 31, the support 31 and the perforated body 32 need not be integrally formed. For example, in the wick 30 in which a copper pillar as the support 31 and a copper mesh as the perforated body 32 are fixed by diffusion bonding, spot welding, or the like, it is difficult to bond the support 31 and the perforated body 32 to each other over the entire surface, and thus a gap is generated in a part between the support 31 and the perforated body 32. In such a wick 30, since the boundary between the support 31 and the perforated body 32 can be discriminated, the support 31 and the perforated body 32 are not integrally formed, but it can be said that the perforated body 32 is made of the material that is the same as the material of the support 31.

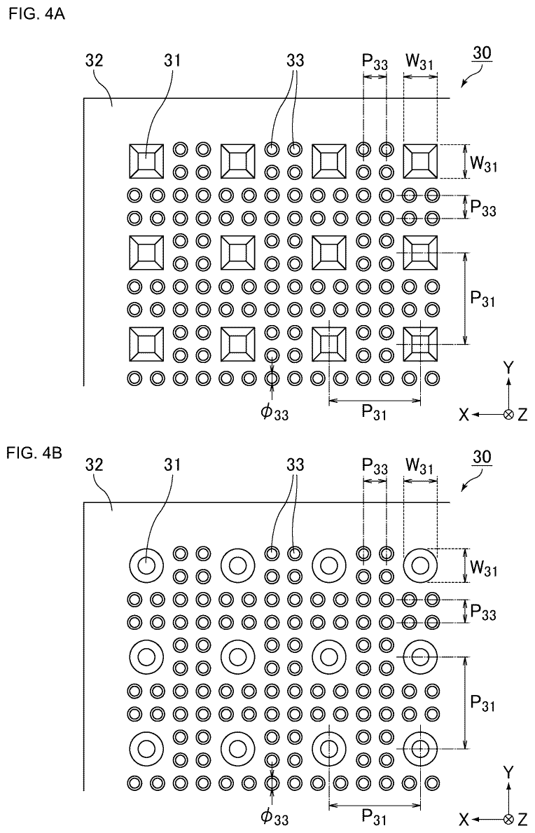

FIG. 4A is an example of a plan view of the wick illustrated in FIG. 3A when viewed from the support side. FIG. 4B is another example of a plan view of the wick illustrated in FIG. 3A when viewed from the support side.

In the wick 30, the support 31 includes, for example, a plurality of columnar members. By holding the working medium 20 in a liquid phase between the columnar members, the heat transport performance of the vapor chamber 1 can be improved. Here, the term “columnar” means a shape in which a ratio of a length of a long side of a bottom surface is less than five times a length of a short side of the bottom surface.

A shape of the columnar member is not particularly limited, and examples thereof include a cylindrical shape, a square columnar shape, a truncated cone shape, and a truncated pyramid shape. In the example illustrated in FIG. 4A, a cross-sectional shape perpendicular to a height direction of the support 31 is a quadrangular shape, and in the example illustrated in FIG. 4B, the cross-sectional shape perpendicular to the height direction of the support 31 is a circular shape.

The columnar member need only have a height relatively higher than a height of the periphery. Therefore, the columnar member includes a portion of which a height is relatively high due to a recess formed in the first inner wall surface 11a, in addition to a portion that protrudes from the first inner wall surface 11a.

A shape of the support 31 is not particularly limited, but as illustrated in FIGS. 2 and 3A, it is preferable that the support 31 has a tapered shape in which a width is narrowed from the perforated body 32 toward the first inner wall surface 11a. As a result, it is possible to widen a flow passage between the supports 31 on the housing 10 side while suppressing the depression of the perforated body 32 between the supports 31. As a result, the transmittance is increased, and the maximum heat transport amount is increased.

The disposition of the supports 31 is not particularly limited, but the supports 31 are preferably disposed uniformly in a predetermined region, and more preferably uniformly over the entire region, for example, such that a center-to-center distance (pitch) between the supports 31 is constant.

The center-to-center distance between the supports 31 (length indicated by P₃₁ in FIG. 4A or 4B) is, for example, 60 μm to 800 μm. The width of the support 31 (length indicated by W₃₁ in FIG. 4A or 4B) is, for example, 20 μm to 500 μm. The height of the support 31 (length indicated by T₃₁ in FIG. 3A) is, for example, 10 μm to 100 μm.

The perforated body 32 has a through-hole 33 that penetrates the perforated body 32 in the thickness direction Z. In the through-hole 33, the working medium 20 can move due to a capillary phenomenon. It is preferable that the through-hole 33 is provided in a portion in which the support 31 is not present when viewed in the thickness direction Z. A shape of the through-hole 33 is not particularly limited, but is preferably a circular shape or an elliptical shape in a cross section on a plane perpendicular to the thickness direction Z.

The disposition of the through-holes 33 of the perforated body 32 is not particularly limited, but the through-holes 33 are preferably disposed uniformly in a predetermined region, and more preferably disposed uniformly over the entire region, for example, such that a center-to-center distance (pitch) between the through-holes 33 of the perforated body 32 is constant.

The center-to-center distance between the through-holes 33 of the perforated body 32 (length indicated by P₃₃ in FIG. 4A or 4B) is, for example, 3 μm to 150 μm. A diameter of the through-hole 33 at an end surface on the first inner wall surface 11a side (length indicated by φ₃₃ in FIG. 4A or 4B) is, for example, 100 μm or less. A thickness of the perforated body 32 (length indicated by T₃₂ in FIG. 3A) is, for example, 5 μm to 50 μm. The thickness of the perforated body 32 means the thickness of the perforated body 32 in a portion in which a protrusion portion 34 described below is not provided.

A protrusion portion 34 is provided on a peripheral edge of the through-hole 33 in a direction close to the first inner wall surface 11a.

FIG. 3B is a perspective view schematically illustrating a shape of a protrusion portion of the wick illustrated in FIG. 3A.

The protrusion portion 34 has a first end portion 35 on the first inner wall surface 11a side and a second end portion 36 on the second inner wall surface 12a side.

In the example illustrated in FIG. 3B, a shape of the protrusion portion 34 is a cylindrical shape. As described above, the shape of the protrusion portion 34 is, for example, a cylindrical shape with a flat first end portion 35. In that case, the shape of the protrusion portion 34 may be a square tube shape, or may be a shape having a hollow inside, such as a truncated cone or a truncated pyramid.

In FIG. 3A, the working medium 20 is sucked up into the through-hole 33 by the capillary force by coming into contact with the surface surrounded by the inner wall of the protrusion portion 34. Therefore, in a portion of the wick 30 in which the through-hole 33 is not present when viewed in the thickness direction Z, the liquid level of the working medium 20 is located on the first inner wall surface 11a side with respect to the perforated body 32, but the working medium 20 is sucked up into the through-hole 33. In this way, in the vapor chamber 1, the working medium 20 can be sucked up into the through-hole 33 even in a case where the liquid amount of the working medium 20 is small. Therefore, it is possible to prevent the capillary force from being less likely to be generated in the wick 30 even in a case where the liquid amount of the working medium 20 is small. From the above, the vapor chamber 1 can suppress a deterioration in the heat uniformity performance and the heat transport performance even in a case where the liquid amount of the working medium 20 is small.

In the vapor chamber 1, it is possible to suppress the deterioration in the heat uniformity performance and the heat transport performance even in a case where the liquid amount of the working medium 20 is small, and thus a change in a design value of a liquid feeding amount of the working medium 20 in the manufacturing process, a variation in the liquid feeding amount of the working medium 20 in the manufacturing process, a fluctuation in the liquid amount of the working medium 20 during use, and the like have little influence on the heat uniformity performance and the heat transport performance. That is, it can be said that the vapor chamber 1 has excellent robustness with respect to the liquid amount of the working medium 20.

It is preferable that the protrusion portion 34 is provided on the entire peripheral edge of the through-hole 33. The protrusion portion 34 may be provided only on a part of the peripheral edge of the through-hole 33 as long as the protrusion portion 34 has a shape that allows the working medium 20 to be sucked up by the capillary force.

The protrusion portion 34 may be provided on the peripheral edges of all of the through-holes 33 in the perforated body 32, or may be provided only on the peripheral edges of some of the through-holes 33 in the perforated body 32. In a case where the protrusion portion 34 is provided only on the peripheral edges of some of the through-holes 33 in the perforated body 32, it is preferable that the protrusion portion 34 is provided at least on the peripheral edge of the through-hole 33 located directly above the heat source HS. In a case where the protrusion portion 34 is provided in the through-hole 33 located directly above the heat source HS, it is possible to suppress the occurrence of the evaporation of the working medium 20 in the evaporation portion even in a case where the liquid amount of the working medium 20 is small. The protrusion portion 34 may be provided only on the peripheral edge of the through-hole 33 located directly above the heat source HS.

The through-hole 33 and the protrusion portion 34 can be manufactured, for example, by punching a metal or the like forming the perforated body 32 by performing press working. In the punching performed by the press working, the formation of the protrusion portion, the shape of the protrusion portion, and the like can be adjusted by appropriately adjusting a depth of the punching and the like. The depth of the punching means, for example, how far a punch is pushed in a punching direction in a case where the punching is performed by the punch.

A dimension of the protrusion portion 34 is not particularly limited. For example, a height of the protrusion portion 34 may be larger than the diameter of the through-hole 33, the height of the protrusion portion 34 may be smaller than the diameter of the through-hole 33, or the height of the protrusion portion 34 may be the same as the diameter of the through-hole 33. In the protrusion portion 34 of FIGS. 3A and 3B, the height of the protrusion portion 34 means a distance between the first end portion 35 and the second end portion 36 in the thickness direction Z.

FIG. 3C is a perspective view schematically illustrating another example of the shape of the protrusion portion of the wick illustrated in FIG. 3A.

In the protrusion portion 34 illustrated in FIG. 3C, the first end portion 35 is not flat and has an uneven shape. In a case where the first end portion 35 has an uneven shape, the height of the protrusion portion 34 means a largest distance among the distances between the first end portion 35 and the second end portion 36 in the thickness direction Z.

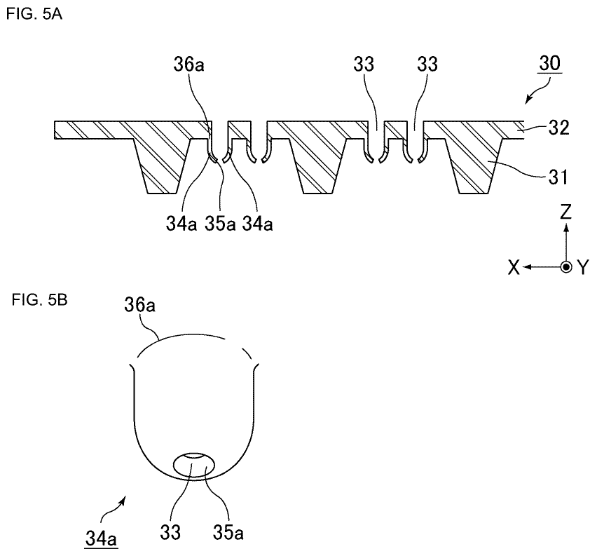

FIG. 5A is a partially enlarged cross-sectional view schematically illustrating a first modification example of the protrusion portion. FIG. 5B is a perspective view schematically illustrating a shape of the protrusion portion illustrated in FIG. 5A.

A protrusion portion 34a illustrated in FIGS. 5A and 5B has a first end portion 35a on the first inner wall surface 11a side and a second end portion 36a on the second inner wall surface 12a side. In the protrusion portion 34a, when viewed in the thickness direction Z, a cross-sectional area of a region surrounded by an inner wall of the first end portion 35a is smaller than a cross-sectional area of a region surrounded by an inner wall of the second end portion 36a. In a case where the cross-sectional area of the region surrounded by the inner wall of the first end portion 35a is smaller than the cross-sectional area of the region surrounded by the inner wall of the second end portion 36a when viewed in the thickness direction Z, the capillary force generated in the region surrounded by the inner wall of the first end portion 35a can be improved. Therefore, the capillary force of the wick 30 can be improved, and thus the maximum heat transport amount of the vapor chamber 1 can be improved.

In the protrusion portion 34a, when viewed in the thickness direction Z, the inner wall of the first end portion 35a may be located on the inside with respect to the inner wall of the second end portion 36a.

The protrusion portion 34a has a tapered shape in which a distance between outer walls of the protrusion portion 34a is narrowed toward a direction close to the first inner wall surface 11a in the cross section along the thickness direction Z.

The protrusion portion 34a has a shape protruding to the first inner wall surface 11a side (lower side in FIG. 5A) in the cross section along the thickness direction Z. In other words, the protrusion portion 34a has a shape that is curved to the first inner wall surface 11a side (lower side in FIG. 5A) with respect to a line segment connecting the first end portion 35a and the second end portion 36a in the cross section along the thickness direction Z.

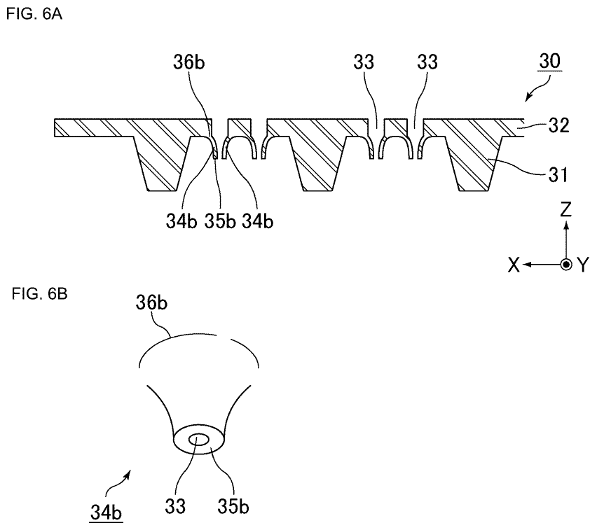

FIG. 6A is a partially enlarged cross-sectional view schematically illustrating a second modification example of the protrusion portion. FIG. 6B is a perspective view schematically illustrating a shape of the protrusion portion illustrated in FIG. 6A.

The protrusion portion 34b illustrated in FIGS. 6A and 6B has a first end portion 35b on the first inner wall surface 11a side and a second end portion 36b on the second inner wall surface 12a side. The protrusion portion 34b has a tapered shape in which a distance between outer walls of the protrusion portion 34b is narrowed toward a direction close to the first inner wall surface 11a in a cross section along the thickness direction Z. The protrusion portion 34b has a shape protruding to the second inner wall surface 12a side (upper side in FIG. 6A) in the cross section along the thickness direction Z. In other words, the protrusion portion 34b has a shape that is curved to the second inner wall surface 12a side (upper side in FIG. 6A) with respect to a line segment connecting the first end portion 35b and the second end portion 36b in the cross section along the thickness direction Z.

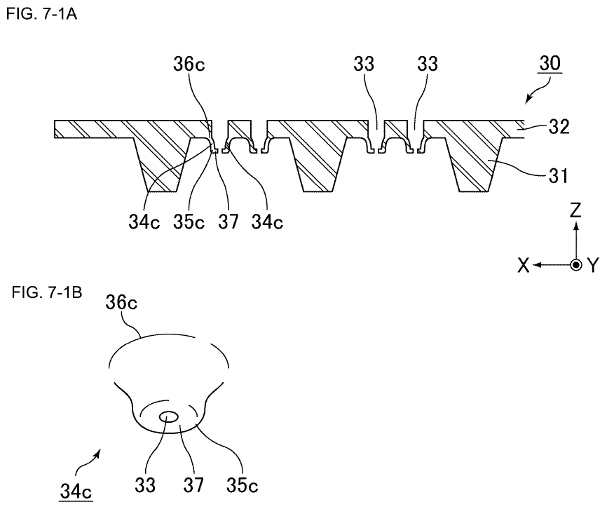

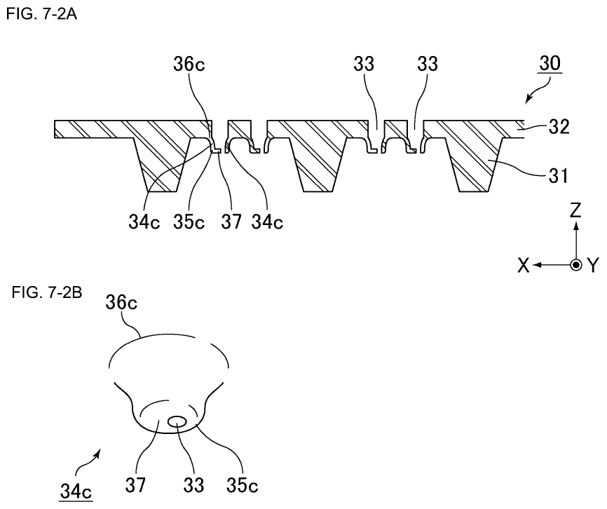

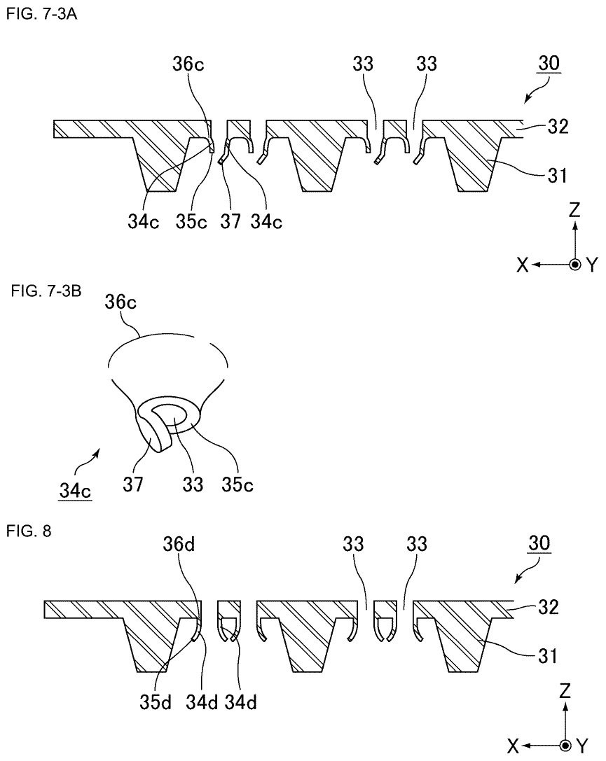

FIG. 7-1A is a partially enlarged cross-sectional view schematically illustrating a third modification example of the protrusion portion. FIG. 7-1B is a perspective view schematically illustrating a shape of the protrusion portion illustrated in FIG. 7-1A.

A protrusion portion 34c illustrated in FIGS. 7-1A and 7-1B has a first end portion 35c on the first inner wall surface 11a side and a second end portion 36c on the second inner wall surface 12a side. In the protrusion portion 34c, when viewed in the thickness direction Z, a cross-sectional area of a region surrounded by an inner wall of the first end portion 35c is smaller than a cross-sectional area of a region surrounded by an inner wall of the second end portion 36c. The protrusion portion 34c includes the lid portion 37 that narrows an opening of the protrusion portion 34c at the first end portion 35c. In the protrusion portion 34c, when viewed in the thickness direction Z, the cross-sectional area of the region surrounded by the inner wall of the first end portion 35c is narrower than that of the protrusion portion 34b in which the lid portion 37 is not provided at the first end portion 35c.

The lid portion 37 that narrows the opening of the protrusion portion 34c may be formed, for example, by performing press working on the first end portion 35c. A size and a shape of the lid portion 37 that narrows the opening of the protrusion portion 34c are not particularly limited, and need only narrow the opening of the protrusion portion 34c on the first end portion 35c side. It is preferable that the lid portion 37 that narrows the opening of the protrusion portion 34c is a flat surface. It is preferable that the lid portion 37 that narrows the opening of the protrusion portion 34c is a flat surface perpendicular to the thickness direction Z. The lid portion 37 that narrows the opening of the protrusion portion 34c may be partially or entirely curved. The lid portion 37 that narrows the opening of the protrusion portion 34c may have a surface having an uneven shape. A thickness of the lid portion 37 that narrows the opening of the protrusion portion 34c may be the same as or different from a thickness of the protrusion portion 34c.

In FIGS. 7-1A and 7-1B, the lid portion 37 is provided on the entire first end portion 35c. In FIGS. 7-1A and 7-1B, the center of the peripheral edge of the through-hole 33 at the first end portion 35c and the center of the peripheral edge of the through-hole 33 at the second end portion 36c match each other.

FIG. 7-2A is a partially enlarged cross-sectional view schematically illustrating another example of the protrusion portion illustrated in FIG. 7-1A. FIG. 7-2B is a perspective view schematically illustrating a shape of the protrusion portion illustrated in FIG. 7-2A.

In FIGS. 7-2A and 7-2B, the lid portion 37 is provided only on a part of the first end portion 35c. In FIG. 7-2A, the lid portion 37 is provided only on a left side portion of the protrusion portion 34c, and the lid portion 37 is not provided on a right side portion of the protrusion portion 34c. In FIGS. 8-2A and 8-2B, the center of the peripheral edge of the through-hole 33 at the first end portion 35c and the center of the peripheral edge of the through-hole 33 at the second end portion 36c do not match each other.

FIG. 7-3A is a partially enlarged cross-sectional view schematically illustrating another example of the protrusion portion illustrated in FIG. 7-1A. FIG. 7-3B is a perspective view schematically illustrating a shape of the protrusion portion illustrated in FIG. 7-3A.

In the protrusion portion 34c illustrated in FIGS. 7-3A and 7-3B, the lid portion 37 is provided only on a part of the first end portion 35c. In FIG. 7-3A, the lid portion 37 is provided only on the right side portion of the protrusion portion 34c, and the lid portion 37 is not provided on the left side portion of the protrusion portion 34c. In FIG. 7-3B, the lid portion having a substantially circular cross section is provided in a part of the first end portion 35c. In FIGS. 7-1A, 7-1B, 7-2A, and 7-2B, the lid portion 37 has a flat surface perpendicular to the thickness direction Z, but in FIGS. 7-3A and 7-3B, the lid portion 37 is provided to extend to the first inner wall surface 11a side (lower side of FIG. 7-3A). In FIGS. 7-3A and 7-3B, the lid portion 37 is a flat surface, but the lid portion 37 may be a curved surface.

FIG. 8 is a partially enlarged cross-sectional view schematically illustrating a fourth modification example of the protrusion portion.

A protrusion portion 34d illustrated in FIG. 8 has a first end portion 35d on the first inner wall surface 11a side and a second end portion 36d on the second inner wall surface 12a side. In the protrusion portion 34d, when viewed in the thickness direction Z, a cross-sectional area of a region surrounded by an inner wall of the first end portion 35d is larger than a cross-sectional area of a region surrounded by an inner wall of the second end portion 36d. In a case where the cross-sectional area of the region surrounded by the inner wall of the first end portion 35d is larger than the cross-sectional area of the region surrounded by the inner wall of the second end portion 36d when viewed in the thickness direction Z, the amount of the working medium 20 sucked up into the through-hole 33 can be increased. In a case where the amount of the working medium 20 sucked up into the through-hole 33 is large, when the working medium 20 in the vapor chamber 1 is reduced, an allowable value of the fluctuation of the working medium 20 until the working medium 20 is no longer sucked up into the through-hole 33 is increased. Therefore, the robustness with respect to the liquid amount of the working medium 20 in the vapor chamber 1 is improved.

In the protrusion portion 34d, when viewed in the thickness direction Z, the inner wall of the first end portion 35d may be located on an outside with respect to the inner wall of the second end portion 36d.

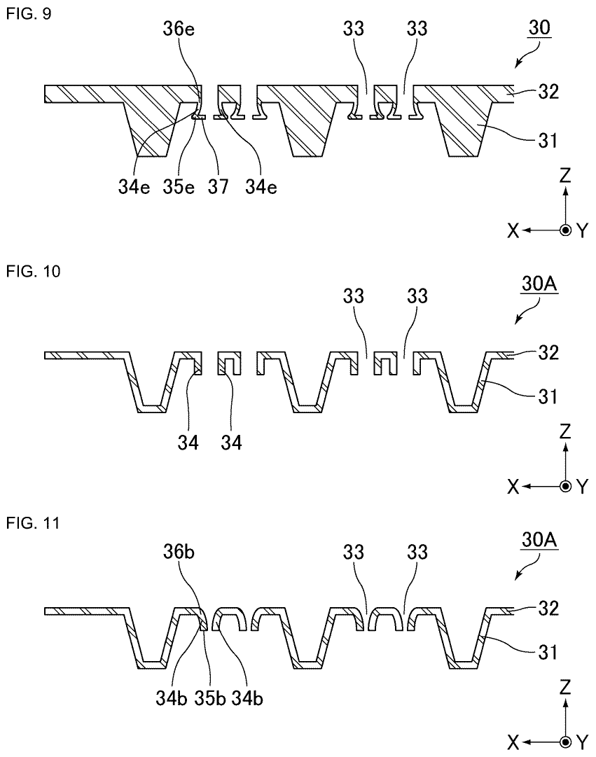

FIG. 9 is a partially enlarged cross-sectional view schematically illustrating a fifth modification example of the protrusion portion.

A protrusion portion 34e illustrated in FIG. 9 has a first end portion 35e on the first inner wall surface 11a side and a second end portion 36e on the second inner wall surface 12a side. In the protrusion portion 34e, when viewed in the thickness direction Z, a cross-sectional area of a region surrounded by an inner wall of the first end portion 35e is larger than a cross-sectional area of a region surrounded by an inner wall of the second end portion 36e. The protrusion portion 34e includes the lid portion 37 that narrows an opening of the protrusion portion 34e at the first end portion 35e. In the protrusion portion 34e, when viewed in the thickness direction Z, the cross-sectional area of the region surrounded by the inner wall of the first end portion 35e is narrower than that of the protrusion portion 34d in which the lid portion 37 is not provided at the first end portion 35e.

The lid portion 37 that narrows the opening of the protrusion portion 34e may be formed, for example, by performing press working on the first end portion 35e. A size and a shape of the lid portion 37 that narrows the opening of the protrusion portion 34e are not particularly limited, and need only narrow the opening of the protrusion portion 34e on the first end portion 35e side. It is preferable that the lid portion 37 that narrows the opening of the protrusion portion 34e is a flat surface. It is preferable that the lid portion 37 that narrows the opening of the protrusion portion 34e is a flat surface perpendicular to the thickness direction Z. The lid portion 37 that narrows the opening of the protrusion portion 34e may be partially or entirely curved. The lid portion 37 that narrows the opening of the protrusion portion 34e may have a surface having an uneven shape. A thickness of the lid portion 37 that narrows the opening of the protrusion portion 34e may be the same as or different from a thickness of the protrusion portion 34e.

FIG. 10 is a partially enlarged cross-sectional view schematically illustrating a first modification example of the wick.

In a wick 30A illustrated in FIG. 10, for example, the support 31 is formed in a recessed portion by bending and recessing a part of metal foil by performing press working or the like. Since a vapor space is formed in the recessed portion of the support 31, the thermal conductivity is improved. The example illustrated in FIG. 10 is not limited, and in a case where the press working is performed on the metal foil, the through-hole may be formed in the recessed portion in a case where a part of the metal foil is bent, depending on a degree of the press working.

It is preferable that a thickness of the metal foil before performing the press working or the like is constant. However, the metal foil may be thinned at the bent portion. From the above, in the wick 30A, it is preferable that the thickness of the support 31 is the same as the thickness of the perforated body 32 or is smaller than the thickness of the perforated body 32.

It is preferable that the wick 30A is formed by collectively performing the press working for forming the support 31 and the press working for forming the through-hole 33 and the protrusion portion 34.

In the wick 30A, the thickness of the protrusion portion 34 may be the same as the thickness of the support 31. In the wick 30A, the thickness of the protrusion portion 34 may be the same as the thickness of the perforated body 32. As illustrated in FIG. 10, in the wick 30A, the thickness of the support 31, the thickness of the perforated body 32, and the thickness of the protrusion portion 34 may be constant.

In the wick 30A, the thickness of the protrusion portion 34 may be different from the thickness of the support 31. In the wick 30A, the thickness of the protrusion portion 34 may be different from the thickness of the perforated body 32.

FIG. 11 is a partially enlarged cross-sectional view schematically illustrating a first modification example of the protrusion portion in the wick illustrated in FIG. 10.

A protrusion portion 34b illustrated in FIG. 11 has the same shape as the protrusion portion 34b illustrated in FIGS. 6A and 6B. The protrusion portion 34b has the first end portion 35b on the first inner wall surface 11a side and the second end portion 36b on the second inner wall surface 12a side. The protrusion portion 34b has a tapered shape in which a distance between the outer walls of the protrusion portion 34b is narrowed toward a direction close to the first inner wall surface 11a in the cross section along the thickness direction Z. The protrusion portion 34b has a shape protruding to the second inner wall surface 12a side (upper side in FIG. 11) in the cross section along the thickness direction Z. In other words, the protrusion portion 34b has a shape that is curved to the second inner wall surface 12a side (upper side in FIG. 11) with respect to a line segment connecting the first end portion 35b and the second end portion 36b in the cross section along the thickness direction Z.

The thickness of the protrusion portion 34b may be the same as or different from the thickness of the support 31. The thickness of the protrusion portion 34b may be the same as or different from the thickness of the perforated body 32.

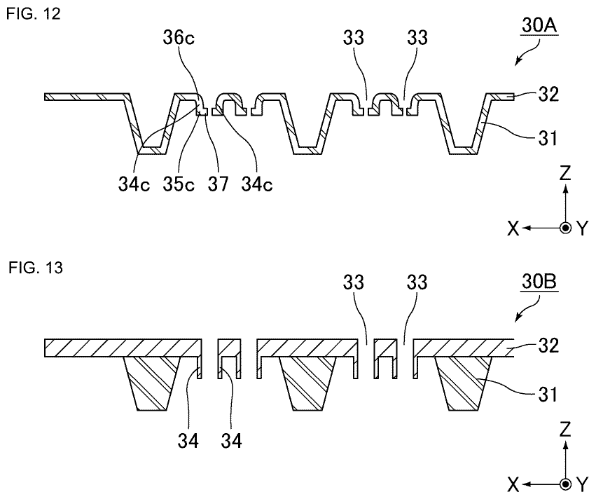

FIG. 12 is a partially enlarged cross-sectional view schematically illustrating a second modification example of the protrusion portion in the wick illustrated in FIG. 10.

The protrusion portion 34c illustrated in FIG. 12 has the same shape as the protrusion portion 34c illustrated in FIGS. 7-1A and 7-1B. The protrusion portion 34c has the first end portion 35c on the first inner wall surface 11a side and the second end portion 36c on the second inner wall surface 12a side. In the protrusion portion 34c, when viewed in the thickness direction Z, the cross-sectional area of the region surrounded by the inner wall of the first end portion 35c is smaller than the cross-sectional area of the region surrounded by the inner wall of the second end portion 36c. The protrusion portion 34c includes the lid portion 37 that narrows the opening of the protrusion portion 34c at the first end portion 35c.

The thickness of the protrusion portion 34c may be the same as or different from the thickness of the support 31. The thickness of the protrusion portion 34c may be the same as or different from the thickness of the perforated body 32. The thickness of the lid portion 37 that narrows the opening of the protrusion portion 34c may be the same as or different from the thickness of the support 31. The thickness of the lid portion 37 that narrows the opening of the protrusion portion 34c may be the same as or different from the thickness of the perforated body 32.

The protrusion portion 34 illustrated in FIG. 10 may have the same shape as the protrusion portion 34a illustrated in FIGS. 5A and 5B, the protrusion portion 34d illustrated in FIG. 8, or the protrusion portion 34e illustrated in FIG. 9.

FIG. 13 is a partially enlarged cross-sectional view schematically illustrating a second modification example of the wick.

In the wick 30B illustrated in FIG. 13, the perforated body 32 is made of a material different from the material of the support 31. The material forming the support 31 is not particularly limited, and examples thereof include a resin, a metal, ceramics, a mixture thereof, and a laminate. The material forming the perforated body 32 is not particularly limited, and examples thereof include a resin, a metal, ceramics, a mixture thereof, and a laminate. A metal is preferable as the material forming the perforated body 32.

The protrusion portion 34 illustrated in FIG. 13 may have the same shape as the protrusion portion 34a illustrated in FIGS. 5A and 5B, the protrusion portion 34b illustrated in FIGS. 6A and 6B, the protrusion portion 34c illustrated in FIGS. 7-1A and 7-1B, the protrusion portion 34c illustrated in FIGS. 7-2A and 7-2B, the protrusion portion 34c illustrated in FIGS. 7-3A and 7-3B, the protrusion portion 34d illustrated in FIG. 8, or the protrusion portion 34e illustrated in FIG. 9.

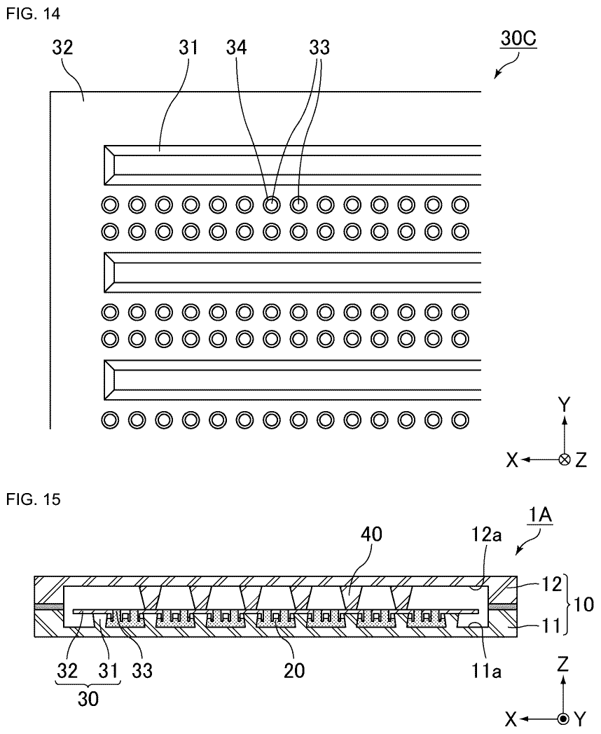

FIG. 14 is a plan view schematically illustrating a third modification example of the wick. FIG. 14 is a plan view of the wick when viewed from the support side.

In a wick 30C illustrated in FIG. 14, the support 31 includes a plurality of rail-shaped members. By holding the working medium 20 in a liquid phase between the rail-shaped members, the heat transport performance of the vapor chamber 1 can be improved. Here, the term “rail-shaped” means a shape in which a ratio of a length of a long side of a bottom surface is equal to or greater than five times a length of a short side of the bottom surface.

A cross-sectional shape of the rail-shaped member perpendicular to a stretching direction is not particularly limited, and examples thereof include a polygonal shape such as a quadrangular shape, a semicircular shape, a semi-elliptical shape, and a shape obtained by combining these shapes.

The rail-shaped member need only have a height relatively higher than a height of the periphery. Therefore, the rail-shaped member includes a portion of which a height is relatively high due to a groove formed in the first inner wall surface 11a, in addition to a portion that protrudes from the first inner wall surface 11a.

In addition, the wick 30C is not limited to the shape illustrated in FIG. 14, and may be used by being partially disposed without being disposed over the entire internal space. For example, the support 31 that is rail-shaped may be provided along an outer periphery in the internal space, and the perforated body 32 having a shape along the outer periphery may be disposed thereon.

As illustrated in FIG. 2, a pillar 40 that is in contact with the second inner wall surface 12a may be disposed in the internal space of the housing 10. The wick 30 and the housing 10 can be supported by disposing the pillar 40 in the internal space of the housing 10.

A material forming the pillar 40 is not particularly limited, and examples thereof include a resin, a metal, ceramics, a mixture thereof, and a laminate. In addition, the pillar 40 may be integrated with the housing 10, and may be formed by, for example, etching the second inner wall surface 12a of the housing 10.

A shape of the pillar 40 is not particularly limited as long as the pillar 40 can support the housing 10 and the wick 30, and examples of a shape of a cross section of the pillar 40 perpendicular to the height direction include a polygonal shape such as a rectangular shape, a circular shape, and an elliptical shape.

The heights of the pillars 40 may be the same as or different from each other in one vapor chamber.

In the cross section illustrated in FIG. 2, a width of the pillar 40 is not particularly limited as long as a strength that can suppress the deformation of the housing 10 is provided, and an equivalent circle diameter of a cross section of an end portion of the pillar 40 perpendicular to the height direction is, for example, 100 μm to 2000 μm, and preferably 300 μm to 1000 μm. The deformation of the housing 10 can be further suppressed by increasing the equivalent circle diameter of the pillar 40. On the other hand, a space for the movement of the vapor of the working medium 20 can be more widely secured by reducing the equivalent circle diameter of the pillar 40.

The disposition of the pillars 40 is not particularly limited, but the pillars 40 are preferably disposed uniformly in a predetermined region, and more preferably uniformly over the entire region, for example, such that a distance between the pillars 40 is constant. Uniform strength can be ensured over the entire vapor chamber 1 by uniformly disposing the pillars 40.

FIG. 15 is a cross-sectional view schematically illustrating a first modification example of the thermal diffusion device.

In a vapor chamber (thermal diffusion device) 1A illustrated in FIG. 15, the support 31 is integrally formed with the first sheet 11 of the housing 10. In the vapor chamber 1A, the first sheet 11 and the support 31 can be manufactured by, for example, an etching technique, a printing technique using a multilayer coating, or other multilayer techniques. As illustrated in FIG. 15, it is preferable that the perforated body 32 is made of a material different from the material of the support 31. In the vapor chamber (thermal diffusion device) 1A, the perforated body 32 may be made of the material that is the same as the materials of the support 31 and the first sheet 11 of the housing 10, or the perforated body 32 may be integrally formed with the support 31 and the first sheet 11 of the housing 10.

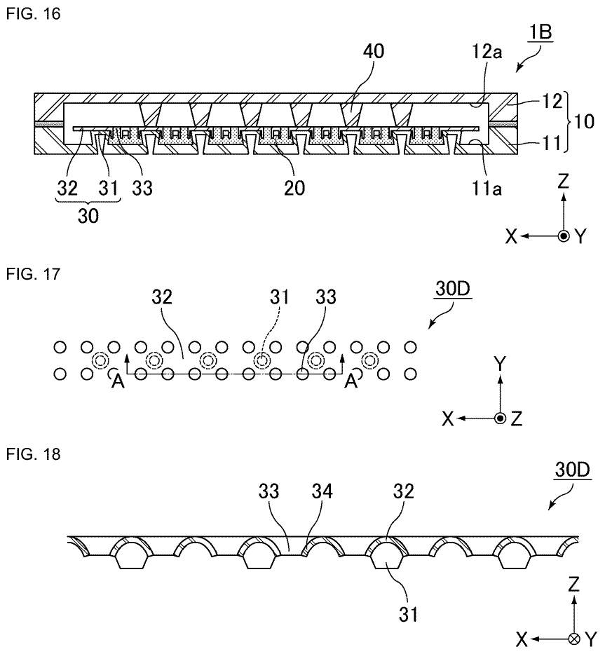

FIG. 16 is a cross-sectional view schematically illustrating a second modification example of the thermal diffusion device.

In a vapor chamber (thermal diffusion device) 1B illustrated in FIG. 16, for example, the support 31 is formed in a recessed portion by bending and recessing a part of the first inner wall surface 11a of the housing 10 by performing press working or the like.

FIG. 17 is a plan view of a first modification example of the wick illustrated in FIG. 3A when viewed from the perforated body side. FIG. 18 is a cross-sectional view of the wick illustrated in FIG. 17, which is taken along a line A-A.

In a wick 30D illustrated in FIG. 18, in the cross section along the thickness direction Z, a curved surface is present and a flat portion is not present between the protrusion portions 34. Although FIG. 18 is a cross-sectional view through the through-hole 33, in a cross section that does not pass through the through-hole 33 in the cross section along the thickness direction Z, a flat portion may be present between the protrusion portions 34 or need not be present between the protrusion portions 34. In addition, in the wick 30D, the entire perforated body 32 may be a curved surface, and a flat portion need not be present.

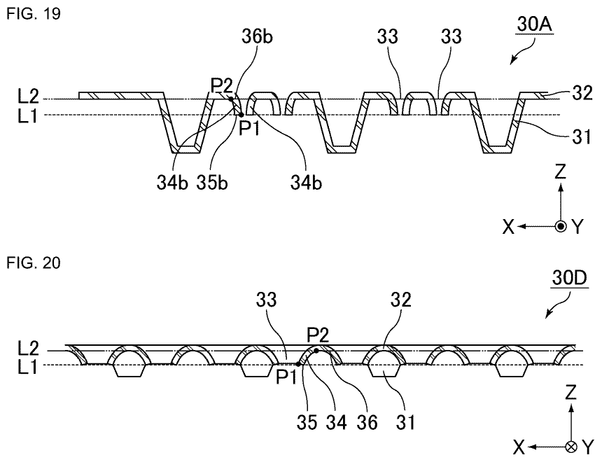

FIG. 19 is a view illustrating the definition of the protrusion portion in the wick illustrated in FIG. 11. FIG. 19 is the same view as FIG. 11 except that a straight line L1 and a straight line L2 are added.

In the present specification, the protrusion portion is defined as a portion between the straight line L1 and the straight line L2 that are set as follows in the cross section along the thickness direction Z. In a case where there are a plurality of protrusion portions, the straight line L1 and the straight line L2 are set for each of the protrusion portions. As illustrated in FIG. 19, in a case where the protrusion portions are present on both sides of the through-hole (both the right side and the left side in FIG. 19) in the cross section along the thickness direction Z, the straight line L1 and the straight line L2 are set for each of the protrusion portions. In the definition of the protrusion portion described below, a plane (XY plane) perpendicular to the thickness direction Z is referred to as a reference plane. Hereinafter, the straight line L1 and the straight line L2 will be described using the wick 30A illustrated in FIG. 19 as an example.

First, a straight line, which passes through a point (point P1 in FIG. 19) present closest to the first inner wall surface 11a side in the first end portion 35b of the protrusion portion 34b present at the peripheral edge of the through-hole 33 on the first inner wall surface 11a side and is parallel to the reference plane, is denoted by L1.

Next, a straight line, which is passes through a point (point P2 in FIG. 19) present closest to the second inner wall surface 12a side on the surface of the wick 30A on the first inner wall surface 11a side and is parallel to the reference plane, is denoted by L2.

In the cross section along the thickness direction Z, a portion of the wick 30A on the straight line L2 is the second end portion 36b. In a case where a plurality of portions of the wick 30A are present on the straight line L2, a portion including the point located at the smallest distance from the peripheral edge of the through-hole 33 on the second inner wall surface 12a side is the second end portion 36b. A portion from the second end portion 36b set as described above to the first end portion 35b is the protrusion portion 34b.

FIG. 20 is a view illustrating the definition of the protrusion portion in the wick illustrated in FIG. 18. FIG. 20 is the same view as FIG. 18 except that the straight line L1 and the straight line L2 are added.

In the wick 30D illustrated in FIG. 20, the straight line L1 and the straight line L2 are set in the same manner as in the wick 30A. In the wick 30D, the curved surface is present and a flat portion is not present between the protrusion portions 34, but a portion on the straight line L2 is the second end portion 36.

The thermal diffusion device according to the present disclosure is not limited to the above-described embodiment, and various applications and modifications can be made within the scope of the present disclosure with respect to the configuration, manufacturing conditions, and the like of the thermal diffusion device.

In the thermal diffusion device according to the present disclosure, the housing may have one evaporation portion or a plurality of evaporation portions. That is, one heat source may be disposed on the outer wall surface of the housing, or a plurality of heat sources may be disposed thereon. The number of evaporation portions and the number of heat sources are not particularly limited.

In the thermal diffusion device according to the present disclosure, in a case where the housing is composed of the first sheet and the second sheet, the first sheet and the second sheet may overlap each other such that the end portions thereof match each other, or may overlap each other such that the end portions thereof are shifted.

In the thermal diffusion device according to the present disclosure, in a case where the housing is composed of the first sheet and the second sheet, the material forming the first sheet may be different from the material forming the second sheet. For example, by using a material having high strength for the first sheet, it is possible to disperse the stress applied to the housing. By making the materials of both the sheets different from each other, one function can be obtained with one sheet and the other function can be obtained with the other sheet. The above-described functions are not particularly limited, and examples thereof include a thermal conductivity function and an electromagnetic wave shield function.

The thermal diffusion device according to the present disclosure can be mounted in an electronic apparatus for heat radiation. Therefore, the present disclosure also includes the electronic apparatus including the thermal diffusion device according to the present disclosure. Examples of the electronic apparatus according to the present disclosure include a smartphone, a tablet terminal, a laptop, a game machine, a wearable device, and the like. As described above, the thermal diffusion device according to the present disclosure can independently operate without requiring an external power to two-dimensionally diffuse heat at a high speed by using latent heat of evaporation and latent heat of condensation of the working medium. Therefore, with the electronic apparatus including the thermal diffusion device according to the present disclosure, it is possible to effectively realize the heat radiation in a limited space inside the electronic apparatus.

The thermal diffusion device according to the present disclosure can be used in various intended uses in the field of a portable information terminal or the like. For example, the thermal diffusion device can be used to lengthen a use time of an electronic apparatus by lowering a temperature of a heat source such as a CPU, and can be used for a smartphone, a tablet terminal, a laptop, and the like.

### REFERENCE SIGNS LIST

1, 1A, 1B vapor chamber (thermal diffusion device)
10 housing
11 first sheet
11a first inner wall surface
12 second sheet
12a second inner wall surface
20 working medium
30, 30A, 30B, 30C, 30D wick
31 support
32 perforated body
33 through-hole
34, 34a, 34b, 34c, 34d, 34e protrusion portion
35, 35a, 35b, 35c, 35d, 35e first end portion
36, 36a, 36b, 36c, 36d, 36e second end portion
37 lid portion
40 pillar
HS heat source
P₃₁ center-to-center distance between supports
P₃₃ center-to-center distance between through-holes
T₃₁ height of support
T₃₂ thickness of the perforated body
W₃₁ width of support
X width direction
Y length direction
Z thickness direction
φ₃₃ diameter of through-hole at end surface on first inner wall surface side

1. A thermal diffusion device comprising:
a housing having a first inner wall surface and a second inner wall surface that face each other in a thickness direction and define an internal space;
a working medium enclosed in the internal space of the housing; and
a wick in the internal space of the housing, wherein the wick includes:
a support that is in contact with the first inner wall surface;
a perforated body that is in contact with the support, the perforated body having a through-hole that penetrates the perforated body in the thickness direction; and
a protrusion portion on a peripheral edge of the through-hole and extending in a direction toward the first inner wall surface.

2. The thermal diffusion device according to claim 1, wherein the protrusion portion has a cylindrical shape.

3. The thermal diffusion device according to claim 2, wherein the protrusion portion has a flat end portion.

4. The thermal diffusion device according to claim 2, wherein the protrusion portion has an uneven end portion.

5. The thermal diffusion device according to claim 1, wherein the protrusion portion extends from an entirety of the peripheral edge of the through-hole.

6. The thermal diffusion device according to claim 1,
wherein the protrusion portion has a first end portion on a first inner wall surface side and a second end portion on a second inner wall surface side, and
when viewed in the thickness direction, a cross-sectional area of a region surrounded by an inner wall of the first end portion is smaller than a cross-sectional area of a region surrounded by an inner wall of the second end portion.

7. The thermal diffusion device according to claim 6, wherein, when viewed in the thickness direction, the inner wall of the first end portion is located on an inside with respect to the inner wall of the second end portion.

8. The thermal diffusion device according to claim 7, wherein the protrusion portion has a tapered shape in which a distance between outer walls of the protrusion portion is narrowed in the direction toward the first inner wall surface in a cross section along the thickness direction.

9. The thermal diffusion device according to claim 1,
wherein the protrusion portion has a first end portion on a first inner wall surface side and a second end portion on a second inner wall surface side, and
when viewed in the thickness direction, a cross-sectional area of a region surrounded by an inner wall of the first end portion is larger than a cross-sectional area of a region surrounded by an inner wall of the second end portion.

10. The thermal diffusion device according to claim 9, wherein, when viewed in the thickness direction, the inner wall of the first end portion is located on an outside with respect to the inner wall of the second end portion.

11. The thermal diffusion device according to claim 6, wherein the protrusion portion includes a lid portion that narrows an opening of the protrusion portion, at the first end portion.

12. The thermal diffusion device according to claim 9, wherein the protrusion portion includes a lid portion that narrows an opening of the protrusion portion, at the first end portion.

13. The thermal diffusion device according to claim 1, wherein a thickness of the support is the same as a thickness of the perforated body.

14. The thermal diffusion device according to claim 1, wherein a thickness of the support is smaller than a thickness of the perforated body.

15. The thermal diffusion device according to claim 1, wherein the perforated body comprises a material that is the same as a material of the support.

16. The thermal diffusion device according to claim 1, wherein the perforated body comprises a material different from a material of the support.

17. The thermal diffusion device according to claim 1, wherein the support includes a plurality of columnar members.

18. The thermal diffusion device according to claim 1, wherein the support includes a plurality of rail-shaped members.

19. An electronic apparatus comprising:
the thermal diffusion device according to claim 1.
